(19) United States
(12) Patent Application Publication
(10) Pub. No.: US 2022/0247621 A1
(43) Pub. Date: Aug. 4, 2022

(54) METHOD, APPARATUS, AND SYSTEM FOR DISTRIBUTED SENSOR MONITORING AND MANAGEMENT IN A SYSTEM-ON-CHIP

(71) Applicant: Ampere Computing LLC, Santa Clara, CA (US)

(72) Inventors: Kha Hong Nguyen, Santa Clara, CA (US); Phil Mitchell, San Jose, CA (US); Sanjay Bhikhubhai Patel, Durham, NC (US)

(21) Appl. No.: 17/166,479

(22) Filed: Feb. 3, 2021

(51) Int. Cl. H04L 12/24; H01L 21/66; G06F 9/4401; G06F 8/65

(52) U.S. Cl. CPC H04L 41/082; G06F 8/65; G06F 9/4411; H01L 22/30

(57) ABSTRACT

Apparatuses, systems, and methods for collecting and managing data from a plurality of sensors across a system-on-a-chip (SoC). In exemplary aspects, an apparatus comprises an external memory and a system management processor coupled to external memory and configured to be programmed by external memory. The apparatus further comprises a plurality of sensor circuits coupled to the system management processor and the external memory and configured to be programmed by the external memory. The external memory stores configuration information for programming each of the plurality of sensor circuits to collect and provide data concurrently with each of the others of the plurality of sensor circuits to be analyzed by a management firmware program and a management firmware program configured to analyze data received at the system management processor from the plurality of sensor circuits. The external memory is configured to program the system management processor and the plurality of sensor circuits.

### BACKGROUND

### I. Field of the Disclosure

The technology of the disclosure relates generally to distributed sensor monitoring on a system-on-chip (SoC), and specifically to the management and collection of data from a plurality of different types of sensors across an SoC.

### II. Background

In order to respond to various conditions and events that may occur across a system-on-chip (SoC), such as a microprocessor, the SoC may include a plurality of different types of sensors. These sensors collect and report information related to the operation of the SoC. This information may be used to respond to various conditions and events that occur during operation of the SoC. Examples of types of sensors that may be used include, but are not limited to, temperature sensors (which measure the temperature at a particular physical location on the SoC) and power event monitors (which observe and report on power events at a particular physical location on the SoC). The information collected by these sensors may allow other control circuits (such as a power management processor or similar) to make changes to the operating parameters of the SoC to mitigate problems related to the conditions and events that the sensors are capable of detecting.

In conventional implementations, an SoC includes a power or system management processor, which is responsible for collecting information from the various sensors that may be present on the SoC, evaluating the information from those sensors, and changing the operating parameters of the SoC accordingly. In such implementations, the management processor individually queries each sensor, and each sensor includes a buffer in which the sensor accumulates data while it waits to be queried by the management processor.

As the physical size of SoCs increases, thus increasing the total physical area across which sensors may be distributed, it is advantageous to concurrently increase the number of sensors. However, increasing the number of sensors may be problematic in conventional implementations, because as the number of sensors increases, the management processor may either spend a longer time interval between successive queries to each sensor (if the amount of data retrieved from each sensor remains constant, as more sensors must now be queried before returning), or the amount of data retrieved from each sensor may be reduced (in order to maintain the same time interval between queries to the same sensor). In either case, this may cause unacceptable degradation in the ability of the management processor to react to the events and conditions that the various sensors may detect, which in some cases may cause unrecoverable faults which necessitate a reboot of the SoC.

This may cause particular problems where the SoC is both relatively physically large (and thus may experience a significant variety of conditions and events across different parts of the physical die) and is operating in a cloud environment which depends on reliable uptime for such SoCs. In the case of such SoCs, the ability of a management processor to adjust to such events and conditions is relatively more important, but conventional implementations may be unable to either respond quickly enough to prevent unnecessary reboots, or may select unacceptably low performance parameters for the SoC to compensate for the lack of quick response. Thus, a system to manage and collect sensor data across a large physical chip that retains the ability to respond quickly to various conditions and events that may be detected by those sensors is desirable.

### SUMMARY OF THE DISCLOSURE

Aspects disclosed in the detailed description include a system for collecting and managing data from a plurality of sensors across an SoC, and related apparatus and method.

In this regard in one aspect, an apparatus comprises an external memory and a system management processor coupled to the external memory and configured to be programmed by the external memory. The apparatus further comprises a plurality of sensor circuits coupled to the system management processor and the external memory and configured to be programmed by the external memory. The external memory stores configuration information for programming each of the plurality of sensor circuits to collect and provide data concurrently with each of the others of the plurality of sensor circuits to be analyzed by a management firmware program and a management firmware program configured to analyze data received at the system management processor from the plurality of sensor circuits. The external memory is configured to program the system management processor and the plurality of sensor circuits.

In this regard, in another aspect, an apparatus comprises means for storing information and means for system management processing coupled to the means for storing information. The means for system management processing is configured to be programmed by the means for storing information. The apparatus further comprises a plurality of means for sensing coupled to the means for system management processing and the means for storing information, and configured to be programmed by the means for storing information. The means for storing information further stores configuration information for programing each of the plurality of means for sensing to collect and provide data concurrently with each of the others of the plurality of means for sensing to be analyzed by means for analyzing sensor data, and means for analyzing sensor data configured to analyze data from the plurality of means for sensing. The means for storing information is configured to program the means for system management processing and the means for sensing.

In this regard, in yet another aspect, a method comprises programming a plurality of sensors to collect and concurrently provide data, and programming a system management processor with management firmware configured to analyze data collected from the plurality of sensors. The method further comprises concurrently receiving data from the plurality of sensor circuits at the management processor, and determining a response by the management firmware based on analyzing the concurrently-received data.

In this regard, in yet another aspect, a non-transitory computer-readable medium having stored thereon computer executable instructions which, when executed by a processor, cause the processor to program a plurality of sensors to collect and concurrently provide data and program a system management processor with management firmware configured to analyze data collected from the plurality of sensors. The instructions further cause the processor to concurrently receive data from the plurality of sensor circuits by the management processor and determine a response by the management firmware based on analyzing the concurrently-received data.

### BRIEF DESCRIPTION OF THE FIGURES

FIG. 1 is a block diagram of a system for managing and collecting data from a plurality of sensors across an SoC;

FIG. 2 is a block diagram of an aspect of a sensor circuit which may be managed and from which data may be collected as described further herein;

FIG. 3 is a block diagram of a method of managing and collecting data from a plurality of sensors across an SoC; and

FIG. 4 is a block diagram of a processor-based system that can collect and manage data from a plurality of sensors across an SoC.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include [to be completed after claims are approved].

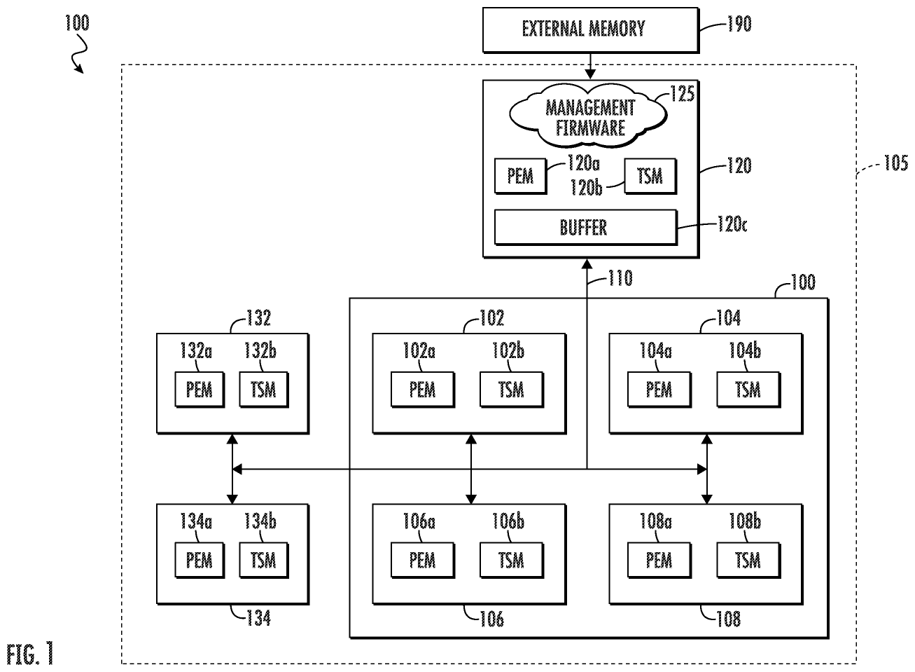

In this regard, FIG. 1 is a block diagram of a system 100 for managing and collecting data from a plurality of sensor circuits (also referred to herein as “sensors”) across an SoC 105. The SoC 105 includes a processor complex 100 which is coupled to a first memory controller 132, a second memory controller 134, and a system management processor 120 via a system bus 110. The processor complex 100 includes a first processing core 102, a second processing core 104, a third processing core 106, and a fourth processing core 108. Each of the processing cores 102-108 has an associated respective power event monitor (“PEM”) 102a-108a and an associated respective temperature sensor monitor (“TSM”) 102b-108b. Likewise, each of the memory controllers 132-134 has an associated power event monitor 132a-134a and an associated temperature sensor monitor 132b-134b. The system management processor 120 includes a power event monitor 120a, a temperature sensor monitor 120b, and a sensor data buffer 120c. As will be described further herein, the system management processor 120 may be programmed by an external memory 190 to run a management firmware program 125, which may analyze data received from the power event monitors 102a-108a, 120a, and 132a-134a (which together may be collectively referred to herein as the “SoC power event monitors”) and temperature sensor monitors 102b-108b, 120b, and 132b-134b (which together may be collectively referred to herein as the “SoC temperature sensor monitors”) and may determine a response based on the data received from the SoC power event monitors and SoC temperature sensor monitors.

In order to provide concurrent information from across the SoC 105, the power event monitors 102a-108a, 120a, and 132a-134a and the temperature sensor monitors 102b-108b, 120b, and 132b-134b (all of which together may be collectively referred to as the “SoC sensors”) may be programmable, and thereafter may concurrently communicate with the system management processor 120, either independently or in response to a single triggering event. The power event monitors 102a-108a, 120a, and 132a-134a, and the temperature sensor monitors 102b-108b, 120b, and 132b-134b may be configured to be programmed as part of a firmware programming by the external memory 190 of the SoC 105 (which may also include programming the management firmware program 125 of the system management processor 12) during power-on and boot time of the SoC 105, as part of a reset of the SoC 105, or at other times that may be determined by those having skill in the art.

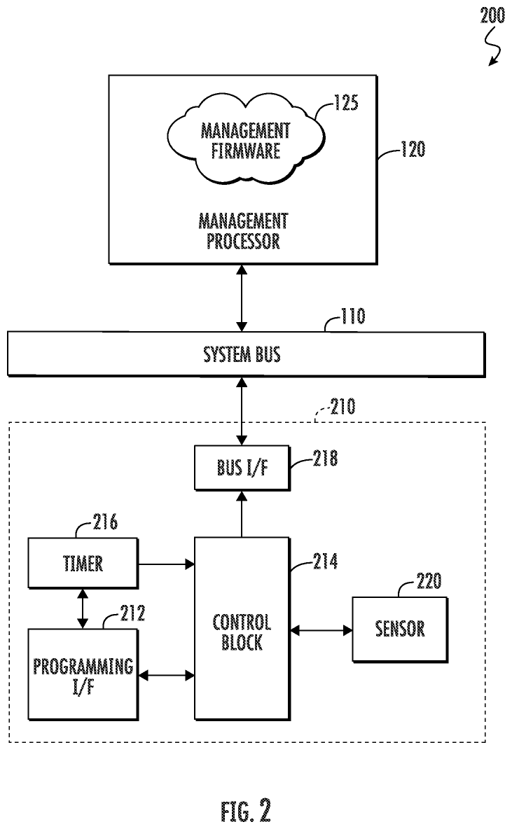

As will be discussed in more detail with respect to FIG. 2, each of the SoC sensors may be programmed to collect data and concurrently provide the collected data back to the system management processor 120 at a programmed rate, in some cases without being queried by the system management processor 120, and in other cases, in response to a single triggering event. Programming the SoC sensors in this way allows all of the SoC sensors to concurrently and/or independently provide their collected data back to the sensor data buffer 120c over the system bus 110 for storage and use by the system management processor 120. In one aspect, the SoC temperature sensor monitors may be programmed to independently (i.e., not in response to a specific triggering event or query from the management firmware program 125) and concurrently provide data back to the system management processor 120 at a programmed rate over the system bus 110, while the SoC power event monitors may be programmed to concurrently provide data back to the system management processor 120 over the system bus 110 in response to a triggering event received from the management firmware program 125.

In one aspect, the management firmware program 125 may analyze data received from the power event monitors at a first time interval, and may analyze data received from the temperature sensor monitors at a second time interval. The first time interval and the second time interval may be the same, or may be different; in one aspect, the first time interval may be 100 microseconds, and the second time interval may be 10 milliseconds. In the context of the present disclosure, “concurrent” need not be simultaneous or substantially simultaneous, but rather may simply indicate that the data for the particular type of sensor can be updated within the associated time interval (i.e., for power event monitors, all of the power event monitors are able to communicate their data back to the management firmware program 125 over the system bus 110 within the first time interval of 100 microseconds, and for temperature sensor monitors, all of the temperature sensor monitors are able to communicate their data back to the management firmware program 125 over the system bus 110 within the second time interval of 10 milliseconds). As those having skill in the art will appreciate, the exact intervals are a matter of design choice, and may be chosen based on the size of the SoC 105, the number of sensors of both types, the complexity and speed of the interconnect over which the sensors communicate with the management firmware program 125, the desired speed of response of the management firmware program 125 to power or temperature events in the SoC 105, and others that may occur to those having skill in the art.

In the aspect depicted in FIG. 1, the power event monitors 102a-108a and 132a-134a and the temperature sensor monitors 102b-108b and 132b-134b may be coupled to the system bus 110, and may both be programmed as described above and may provide their collected data back to the system management processor 120 via the system bus, while the power event monitor 120a and the temperature sensor monitor 120b for the system management processor 120 may be directly programmed and may directly provide their collected data back to the system management processor 120. However, those having skill in the art will recognize that other ways of coupling the SoC sensors and the system management processor 120 are possible and are explicitly within the scope of the teachings of the present disclosure. For example, instead of using a common system bus such as system bus 110, a separate interface could be used either for programming the SoC sensors, for collecting data from the SoC sensors, or both. Similarly, the power event monitor 120a and the temperature sensor monitor 120b of the system management processor 120 could be programmed by either of the above-described interfaces instead of being programmed directly, and could likewise have their data collected by either of the above-described interfaces instead of directly by the system management processor 120.

The data collected from all of the SoC sensors is stored in the sensor data buffer 120c, and the management firmware program 125 may evaluate the data in the sensor data buffer 120c and determine a response to events and conditions in the SoC 105 based on that data. Because the data in the sensor data buffer 120c was collected substantially concurrently (i.e., was updated within the associated time interval as described above) from all the SoC sensors across the entire physical area of the SoC 105, the management firmware program 125 may be able to determine a response that is relatively quicker and more targeted than would have been possible with a more conventional design. For example, the management firmware program 125 may evaluate temperature data from all of the temperature sensor monitors 102b-108b, 120b, and 132b-134b, and may determine that only the fourth processing core 108 is nearing a thermal limit (based on the data from temperature sensor monitor 108b). Thus, instead of lowering the frequency across the entire SoC 105, the management firmware program 125 may be able to lower the frequency of only the fourth processing core 108, while maintaining better performance across the rest of the SoC 105. Similarly, the management firmware program 125 may evaluate power data from all of the power event monitors 102a-108a, 120a, and 132a-134a, and may be able to determine that based on a sum of all the power data that the SoC 105 is approaching its maximum thermal design power (TDP) and that the second processing core 104 is the largest contributor. Based on this determination, the management firmware program 125 may take action to reduce the power consumption of the second processing core 104 while allowing the rest of the SoC 105 to operate normally. Further, the management firmware program 125 may report the data in the sensor data buffer 120c to an operating system or a hypervisor, which may take advantage by scheduling new processes on processing cores that are at relatively lower temperatures than other processing cores, as an example.

FIG. 2 is a block diagram of a portion of a system 200 having a sensor circuit 210 which may be managed and from which data may be collected as was described with respect to FIG. 1. The sensor circuit 210 may be coupled to a system bus such as the system bus 110 of FIG. 1, and may be programmed during firmware programming of the SoC 105 to provide data to a system management processor such as the system management processor 120 of FIG. 1 for use by the management firmware program 125, in an aspect.

The sensor circuit 210 includes a bus interface 218 coupling the sensor circuit 210 to a system bus 110 as described above, and a programming interface 212 which is responsive to being programmed as described above, and which may be coupled to the system management processor via the system bus 110 (and alternatively through the bus interface 218) or may be coupled to the system management processor via a separate interface. The programming interface 212 is coupled to a timer 216 and a control block 214, and may provide an interface for programming either or both the timer 216 and the control block 214 by the system management processor 120. The control block 214 is coupled to and responsive to the timer 216, and couples to the sensor 220 and the bus interface 218. The control block 214 may allow the sensor circuit 210 to provide data back to the system management processor 120 by initiating a transaction on the system bus 110, either independently based on the programming of the timer 216, in response to a triggering event from the management firmware program 125 as described with respect to FIG. 1, or both. The sensor may be a temperature sensor, a power sensor, or other types of sensors employed in integrated circuits that are known to those having skill in the art. Thus, the power event monitors 102a-108a, 120a, and 132a-134a and the temperature sensor monitors 102b-108b, 120b, and 132b-134b of FIG. 1 may all represent aspects of the sensor circuit 210.

In an aspect where the sensor 220 is a temperature, sensor, the programming interface 212 may program the timer 216 with a rate at which the control block 214 is to sample data from the sensor 220 and provide that data to the system management processor via the bus interface 218 and the system bus 110. The programming interface 212 may in some aspects further program the control block 214 with information such as a memory address of the system management processor to which data from the sensor 220 should be written, a specific temperature threshold that represents an “over temperature” condition (which may be provided as additional information back to the system management processor when the temperature value from the sensor 220 exceeds this threshold), and other related information. The information described above with which the sensor is programmed may be referred to as “configuration information.”

In an aspect where the sensor 220 is a power event sensor, the programming interface 212 may again program the timer 216 with a time period over which the control block 214 is to sample data from the sensor 220, and may program the control block 214 to provide data back to the system management processor 120 in response to a triggering event from the management firmware program 125. In some aspects, the programming interface 212 may additionally program the control block 214 with a memory address of the system management processor to which data from the sensor 220 should be written, and a number of samples over which to compute a running weighted average value of samples from subsequent time periods, which is provided back to the system management processor via the bus interface 218 and the system bus 110. Again, the information described above with which the sensor is programmed may be referred to as “configuration information.”

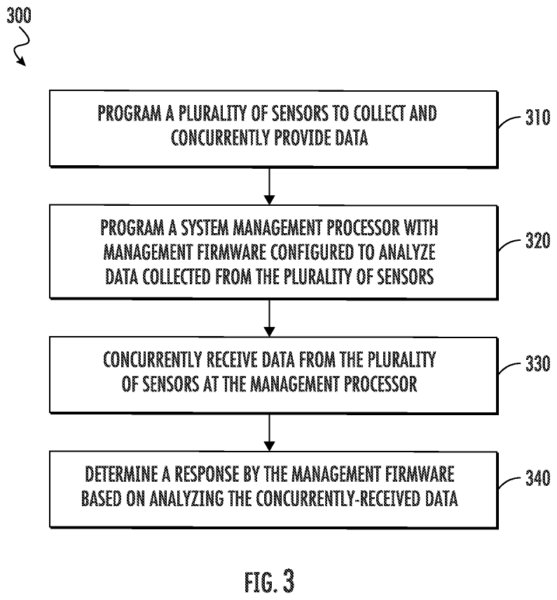

FIG. 3 is a block diagram of a method 300 of managing and collecting data from a plurality of sensors across an SoC, such as the sensors 102a-108a, 120a, and 132a-134a 102b-108b, 120b, and 132b-134b in the SoC 105 in FIG. 1. The method begins in block 310 by programming a plurality of sensors to collect and concurrently provide data. For example, the external memory 190 may program the power event monitors 102a-108a, 120a, and 132a-134a and the temperature sensor monitors 102b-108b, 120b, and 132b-134b of FIG. 1 as described in more detail with respect to FIG. 2 as part of a firmware programming of the SoC 105.

The method then proceeds to block 320, by programming a management processor with management firmware configured to analyze data collected from the plurality of sensors. For example, the system management processor 120 may be programmed with the management firmware program 125 by the external memory 190 as part of a firmware programming of the SoC 105, and the management firmware program 125 may be configured to independently analyze data from the SoC temperature sensor monitors and the SoC power event monitors, as described with respect to FIG. 1.

The method then proceeds to block 330, by concurrently receiving data from the plurality of sensors at the management processor. For example, the system management processor 120 receives data written into the sensor data buffer 120 from the power event monitors 102a-108a, 120a, and 132a-134a in response to a triggering event from the management firmware program 125, and from the temperature sensor monitors 102b-108b, 120b, and 132b-134b independently as programmed, via the system bus 110, as described with respect to FIG. 1.

The method then proceeds to block 340, by determining a response by the management firmware program 125 based on the concurrently-received data. For example, the management firmware program 125 may determine that one of the processing cores 102-108 should have its frequency reduced in response to data showing that a temperature sensor monitors 102a-108a associated with that processing core 102-108 is causing the SoC 105 to approach its TDP. Further, those having skill in the art will recognize that other responses are possibly, and are explicitly within the scope of the teachings of the present disclosure. In one aspect, the management firmware program 125 may determine that although an instantaneous power limit has been reached, a thermal limit has not been reached, and thus may allow the SoC 105 to temporarily exceed the instantaneous power limit, so long as an average power limit over a time period is not exceeded. In another aspect, where the system bus 110 is clocked independently of the processing cores 102-108, the memory controllers 132-134, and the system management processor 120, if the management firmware program 125 determines that all other parts of the SoC 105 are running at a maximum frequency but either an instantaneous or average power limit has not been reached, the management firmware program 125 may allow the system bus 110 to run at a higher frequency to take advantage of the power headroom.

The exemplary system-on-chip including a system management processor and management firmware program for collecting and managing data from a plurality of sensor circuits across an SoC that may according to aspects disclosed herein and discussed with reference to FIGS. 1-3 may be provided in or integrated into any processor-based device. Examples, without limitation, include a server, a computer, a portable computer, a desktop computer, a mobile computing device, a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a wearable computing device (e.g., a smart watch, a health or fitness tracker, eyewear, etc.), a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

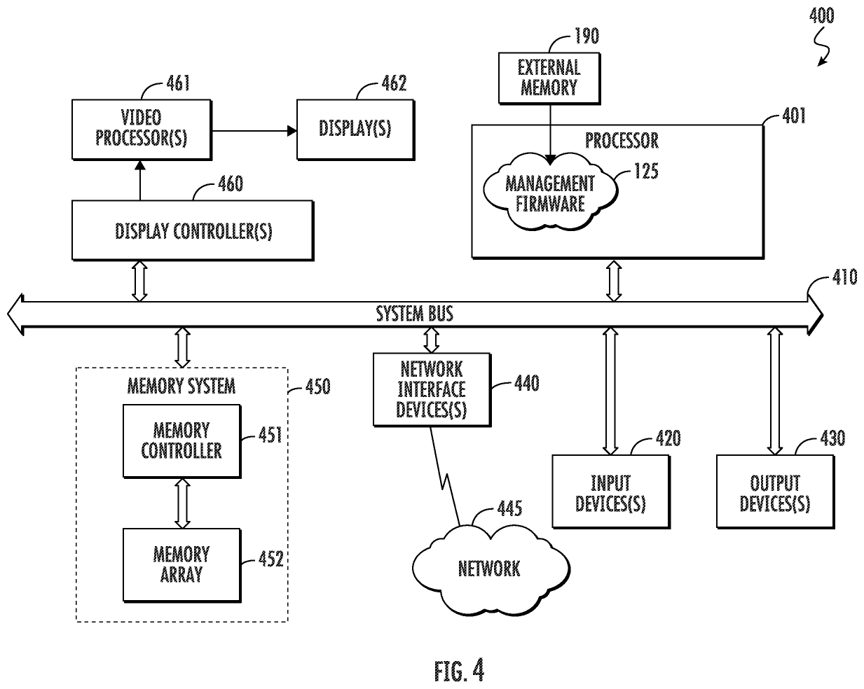

In this regard, FIG. 4 illustrates an example of a processor-based system 400 that can collect and manage data from a plurality of sensors across an SoC as illustrated and described with respect to FIGS. 1-3. In this example, the processor-based system 400 includes a processor SoC 401 (which may have one or more central processing units (CPUs), each including one or more processor cores), and which may correspond to the processor complex 100 of FIG. 1, and as such may include the management firmware program 125 (which may be executed on an included system management processor 120, or another CPU of the processor-based system 400), which may be configured to collect and manage data from a plurality of sensors across an SoC as illustrated and described with respect to FIGS. 1-3. The processor SoC 401 may be a master device, and is coupled to a system bus 410 and can intercouple master and slave devices included in the processor-based system 400. As is well known, the processor SoC 401 communicates with these other devices by exchanging address, control, and data information over the system bus 410. For example, the processor SoC 401 can communicate bus transaction requests to a memory controller 451 as an example of a slave device. Although not illustrated in FIG. 4, multiple system buses 410 could be provided, wherein each system bus 410 constitutes a different fabric.

Other master and slave devices can be connected to the system bus 410. As illustrated in FIG. 4, these devices can include a memory system 450, one or more input devices 420, one or more output devices 430, one or more network interface devices 440, and one or more display controllers 460, as examples. The input device(s) 420 can include any type of input device, including, but not limited to, input keys, switches, voice processors, etc. The output device(s) 430 can include any type of output device, including, but not limited to, audio, video, other visual indicators, etc. The network interface device(s) 440 can be any devices configured to allow exchange of data to and from a network 445. The network 445 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 440 can be configured to support any type of communications protocol desired. The memory system 450 can include the memory controller 451 coupled to one or more memory units 452.

The processor SoC 401 may also be configured to access the display controller(s) 460 over the system bus 410 to control information sent to one or more displays 462. The display controller(s) 460 sends information to the display(s) 462 to be displayed via one or more video processors 461, which process the information to be displayed into a format suitable for the display(s) 462. The display(s) 462 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

1. An apparatus, comprising:
an external memory,
a system management processor coupled to the external memory, and configured to be programmed by the external memory, and
a plurality of sensor circuits coupled to the system management processor and the external memory, and configured to be programmed by the external memory;
the external memory storing:
configuration information for programming each of the plurality of sensor circuits to collect and provide data concurrently with each of the others of the plurality of sensor circuits to be analyzed by a management firmware program; and
the management firmware program configured to analyze data received at the system management processor from the plurality of sensor circuits,
the external memory configured to program the system management processor and the plurality of sensor circuits.

2. The apparatus of claim 1, wherein the plurality of sensor circuits includes at least a first temperature sensor monitor and at least a first power event monitor, and wherein the management firmware program is configured to independently analyze the data from the first temperature sensor monitor and the first power event monitor.

3. The apparatus of claim 2, wherein the management firmware program is configured to analyze the data from the first temperature sensor monitor at a first time interval and to analyze the data from a second temperature sensor monitor at a second time interval.

4. The apparatus of claim 3, wherein the first time interval is different from the second time interval.

5. The apparatus of claim 4, wherein the first time interval is longer than the second time interval.

6. The apparatus of claim 2, wherein the configuration information for the first temperature sensor monitor is configured to program the first temperature sensor monitor to provide data to the system management processor independently.

7. The apparatus of claim 2, wherein the configuration information for the first power event monitor is configured to program the first power event monitor to provide data to the system management processor in response to a triggering event received from the management firmware program.

8. The apparatus of claim 2, wherein the plurality of sensor circuits includes a plurality of temperature sensor monitors and a plurality of power event monitors, and wherein management firmware program is configured to determine a response based on the data concurrently received from the plurality of temperature sensor monitors and the plurality of power event monitors.

9. The apparatus of claim 8, wherein the management firmware program is configured to determine that only the first temperature sensor monitor associated with a first processing core is approaching a thermal limit, and to respond by taking an action to reduce the temperature of only the first processing core.

10. The apparatus of claim 8, wherein the management firmware program is configured to determine that a first processing core associated with the first power event monitor is consuming more power than a second processing core associated with a second power event monitor, and to respond by reducing the power consumption of only the first processing core.

11. The apparatus of claim 1, further integrated into a device selected from the group consisting of: a server, a computer, a portable computer, a desktop computer, a mobile computing device, a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a wearable computing device (e.g., a smart watch, a health or fitness tracker, eyewear, etc.), a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

12. An apparatus, comprising:
means for storing information,
means for system management processing coupled to the means for storing information, and configured to be programmed by the means for storing information, and
a plurality of means for sensing coupled to the means for system management processing and the means for storing information, and configured to be programmed by the means for storing information;
the means for storing information storing:
configuration information for programming each of the plurality of means for sensing to collect and provide data concurrently with each of the others of the plurality of means for sensing to be analyzed by means for analyzing sensor data; and
the means for analyzing sensor data configured to analyze data from the plurality of means for sensing,
the means for storing information configured to program the means for system management processing and the means for sensing.

13. A method, comprising:
programming a plurality of sensors to collect and concurrently provide data;
programming a system management processor with management firmware configured to analyze data collected from the plurality of sensors;
concurrently receiving data from a plurality of sensor circuits at the management processor; and
determining a response by the management firmware based on analyzing the concurrently-received data.

14. The method of claim 13, wherein programming the plurality of sensors to collect and concurrently provide data comprises programming at least a first temperature sensor monitor to provide data to the system management processor independently and programming at least a first power event monitor to provide data to the system management processor in response to a triggering event received from the management firmware.

15. The method of claim 13, wherein the plurality of sensors includes a plurality of temperature sensor monitors and a plurality of power event monitors, and wherein determining the response by the management firmware based on analyzing the concurrently-received data comprises analyzing the data received from the temperature sensor monitors at a first time interval and analyzing the data received from the power event monitors at a second time interval.

16. The method of claim 15, wherein the first time interval is longer than the second time interval.

17. The method of claim 13, wherein determining the response by the management firmware based on analyzing the concurrently-received data comprises determining that only a first temperature sensor monitor of a plurality of temperature sensor monitors associated with a first processing core is approaching a thermal limit, and taking an action to reduce the temperature of only the first processing core.

18. The method of claim 13, wherein determining the response by the management firmware based on analyzing the concurrently-received data comprises determining that a first processing core associated with a first power event monitor of a plurality of power event monitors is consuming more power than a second processing core associated with a second power event monitor of the plurality of power event monitors, and taking an action to reduce the power consumption of only the first processing core.

19. A non-transitory computer-readable medium having stored thereon computer-executable instructions which, when executed by a processor, cause the processor to:
program a plurality of sensors to collect and concurrently provide data;
program a system management processor with management firmware configured to analyze data collected from the plurality of sensors;
concurrently receive data from a plurality of sensor circuits by the management processor; and
determine a response by the management firmware based on analyzing the concurrently-received data.

20. The non-transitory computer-readable medium of claim 19, wherein the instructions further cause the processor to:
program at least a first temperature sensor monitor to provide data to the system management processor independently; and
program at least a first power event monitor to provide data to the system management processor in response to a triggering event received from the management firmware.
